(19) United States
(12) Patent Application Publication
(10) Pub. No.: US 2025/0307504 A1
(43) Pub. Date: Oct. 2, 2025

(54) OPTIMIZED GPU IMPLEMENTATION OF GRID REFINEMENT IN THE LATTICE BOLTZMANN METHOD

(71) Applicant: Autodesk, Inc., San Francisco, CA (US)

(72) Inventors: Ahmed Hassan Mahmoud Elsayed, Somerville, MA (US); Massimiliano Meneghin, Tambre (IT); Hesam Salehipour, Richmond Hill (CA)

(21) Appl. No.: 19/040,748

(22) Filed: Jan. 29, 2025

Related U.S. Application Data
(60) Provisional application No. 63/572,019, filed on Mar. 29, 2024.

(51) Int. Cl. G06F 30/28

(52) U.S. Cl. CPC G06F 30/28

(57) ABSTRACT

Methods, systems, and apparatus, including medium-encoded computer program products include: obtaining a representation of lattice cells of a discretized domain, the discretized domain includes a first level including first lattice cells and a second level including second lattice cells, the first lattice cells include a first layer of first interface lattice cells and the second lattice cells include a second layer of second interface lattice cells; allocating a ghost layer at the first level; defining, for each lattice cell, velocity distributions along lattice directions; performing at least one first time step of a lattice Boltzmann modelling process, wherein performing the at least one first time step includes performing a first accumulate operation to store, on the ghost layer, velocity distributions of the second layer of second interface cells; and providing a result of the at least one first time step of the lattice Boltzmann simulation.

### CROSS-REFERENCE TO RELATED APPLICATIONS

This specification claims the benefit of priority of U.S. Patent Application No. 63/572,019, entitled “OPTIMIZED GPU IMPLEMENTATION OF GRID REFINEMENT IN THE LATTICE BOLTZMANN METHOD”, filed Mar. 29, 2024, the entire contents of which are hereby incorporated by reference.

### BACKGROUND

This specification relates to performance enhancement and memory management in processing systems, and in particular, to efficient implementation of grid refinement in the implementation of lattice Boltzmann methods.

The lattice Boltzmann method is a widely used technique in computational fluid dynamics. The lattice Boltzmann method is particularly well-suited for implementation on Graphics Processing Units (GPUs) due to their regular and localized data access patterns. However, lattice Boltzmann is inherently memory-bound, which poses challenges for its adaptation for implementation on modem computer architectures. This added complexity may also hinder data locality and can make performance optimization techniques, such as kernel fusion, impractical or challenging to implement.

### SUMMARY

This specification describes technologies relating to performance enhancement and memory management in processing systems, and in particular, to efficient implementation of grid refinement in the implementation of lattice Boltzmann methods.

In general, one or more aspects of the subject matter described in this specification can be embodied in one or more methods (and also one or more non-transitory computer-readable mediums tangibly encoding instructions that, when executed, cause one or more processors to perform method operations), including: obtaining a representation of lattice cells of a discretized domain, wherein the discretized domain includes a first level including first lattice cells and a second level including second lattice cells, wherein a size of the second lattice cells is smaller than a size of the first lattice cells, wherein the first lattice cells include a first layer of first interface lattice cells and the second lattice cells include a second layer of second interface lattice cells, wherein the first interface lattice cells and the second interface lattice cells are neighboring cells at an interface between the first level and the second level; allocating a ghost layer at the first level, wherein the ghost layer includes a layer of first ghost lattice cells adjacent to the first layer of first interface lattice cells and overlapping the second layer of second interface cells, wherein allocating the ghost layer includes allocating the ghost layer in a shared memory that is accessed by a single hardware processor; defining, for each lattice cell, velocity distributions along lattice directions corresponding to each of a predetermined number of lattice vectors associated with different lattice directions; performing at least one first time step of a lattice Boltzmann modelling process, wherein performing the at least one first time step includes performing a first accumulate operation to store, on the ghost layer, velocity distributions of the second layer of second interface cells; and providing a result of the at least one first time step of the lattice Boltzmann simulation.

These and other aspects can each, optionally, include one or more of the following features. Performing the at least one first time step of the lattice Boltzmann modelling process can further include: performing a first first-level collision operation on the first level to update velocity distributions of the first level; performing a first second-level collision operation on the second level to update velocity distributions of the second level; performing an explosion operation to populate velocity distributions of the second layer of second interface cells using velocity distributions of the first level; performing a first first-level streaming operation on the first level to update velocity distributions of the first level; performing a first second-level streaming operation on the second level to update velocity distributions of the second level; performing a second second-level collision operation on the second level to update velocity distributions of the second level; performing a second accumulate operation to store, on the ghost layer, the velocity distributions of the second layer of second interface cells; performing a second second-level streaming operation on the second level to update the velocity distributions of the second level, and performing a coalesce operation, wherein performing the coalesce operation includes reading and averaging the velocity distributions stored on the ghost layer to update velocity distributions of the first level.

The collision operations and the accumulate operations can be executed in a single computational kernel, wherein the accumulate operations are performed as atomic writes. The explosion operations and the streaming operations can be executed in a single computational kernel. The coalescence operations and the streaming operations can be executed in a single computational kernel. The collision operations and the streaming operations can be executed in a single computational kernel.

The one or more methods can include storing the representation of lattice cells of the discretized domain in a block sparse data structure stack. Storing the representation of lattice cells of the discretized domain in the block sparse data structure stack can include storing first level information in a first block sparse data structure and second level information in a second block sparse data structure and storing ghost layer information. Each first block of the first block sparse data structure can include respective first cells. Each second block of the second block sparse data structure can include respective second cells. Storing ghost layer information can include storing block indices of ghost blocks including the ghost layer. Performing the at least one first time step of the lattice Boltzmann modelling process can include assigning each ghost block to a thread group including threads that use a same portion of the shared memory and assigning each respective lattice cell to a thread of the thread group.

One or more aspects of the subject matter described in this specification can also be embodied in one or more systems including: one or more hardware processors; and a shared memory coupled with at least a single hardware processor of the one or more hardware processors; wherein the single hardware processor is configured to: obtain a representation of lattice cells of a discretized domain, wherein the discretized domain includes a first level including first lattice cells and a second level including second lattice cells, wherein a size of the second lattice cells is smaller than a size of the first lattice cells, wherein the first lattice cells include a first layer of first interface lattice cells and the second lattice cells include a second layer of second interface lattice cells, wherein the first interface lattice cells and the second interface lattice cells are neighboring cells at an interface between the first level and the second level; allocate a ghost layer at the first level, wherein the ghost layer includes a layer of first ghost lattice cells adjacent to the first layer of first interface lattice cells and overlapping the second layer of second interface cells, wherein allocating the ghost layer includes allocating the ghost layer in the shared memory that is accessed by the single hardware processor; define, for each lattice cell, velocity distributions along lattice directions corresponding to each of a predetermined number of lattice vectors associated with different lattice directions; perform at least one first time step of a lattice Boltzmann modelling process, wherein performing the at least one first time step includes performing a first accumulate operation to store, on the ghost layer, velocity distributions of the second layer of second interface cells; and provide a result of the at least one first time step of the lattice Boltzmann simulation.

These and other aspects can each, optionally, include one or more of the following features. The single hardware processor can be configured to perform the at least one first time step of the lattice Boltzmann modelling process by being configured to: perform a first first-level collision operation on the first level to update velocity distributions of the first level; perform a first second-level collision operation on the second level to update velocity distributions of the second level; perform an explosion operation to populate velocity distributions of the second layer of second interface cells using velocity distributions of the first level; perform a first first-level streaming operation on the first level to update velocity distributions of the first level; perform a first second-level streaming operation on the second level to update velocity distributions of the second level; perform a second second-level collision operation on the second level to update velocity distributions of the second level; perform a second accumulate operation to store, on the ghost layer, the velocity distributions of the second layer of second interface cells; perform a second second-level streaming operation on the second level to update the velocity distributions of the second level, and perform a coalesce operation, wherein performing the coalesce operation includes reading and averaging the velocity distributions stored on the ghost layer to update velocity distributions of the first level.

The collision operations and the accumulate operations can be executed in a single computational kernel, wherein the accumulate operations are performed as atomic writes. The explosion operations and the streaming operations can be executed in a single computational kernel. The coalescence operations and the streaming operations can be executed in a single computational kernel. The collision operations and the streaming operations can be executed in a single computational kernel.

The single hardware processor can be further configured to store the representation of lattice cells of the discretized domain in a block sparse data structure stack by being configured to: store the representation of lattice cells of the discretized domain in the block sparse data structure stack by being configured to store first level information in a first block sparse data structure and second level information in a second block sparse data structure; and store ghost layer information by being configured to store block indices of ghost blocks including the ghost layer. Each first block of the first block sparse data structure can include respective first cells. Each second block of the second block sparse data structure can include respective second cells.

The single hardware processor can be configured to perform the at least one first time step of the lattice Boltzmann modelling process by being configured to assign each ghost block to a thread group including threads that use a same portion of the shared memory and assign each respective lattice cell to a thread of the thread group. The single hardware processor can be a graphics processing unit (GPU). The shared memory can be a thread register of the GPU.

Particular embodiments of the subject matter described in this specification can be implemented to realize one or more of the following advantages. The described techniques provide an optimized implementation of grid refinement for lattice Boltzmann simulations. In particular, the described techniques are designed to use GPU hardware efficiently to optimize the GPU implementation of lattice Boltzmann simulations with grid refinement, such as single-GPU implementations. GPU performance is enhanced while minimizing memory access bottlenecks.

The described techniques leverage atomic operations and kernel fusion to optimize memory access patterns, reduce synchronization overhead, and minimize kernel launch latencies. The described techniques improve performance and ensure efficient memory management, resulting in computational speedup and lower memory requirements compared to standard lattice Boltzmann grid refinement implementations designed for distributed systems. This allows large-scale simulations of complex flow patterns (e.g., turbulent flow) in domains of unprecedented size using a single GPU.

Further, the described lattice Boltzmann methods can be applied to computational fluid dynamics processes in several physics domains, e.g., thermal, multiphysics, etc. The results of such processes can be used as input to computer aided manufacturing systems to manufacture three-dimensional structures using additive manufacturing, subtractive manufacturing and/or other manufacturing systems and techniques and/or can be provided as a digital asset, such as for use in animation.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a system usable to facilitate implementation of the described techniques in a lattice Boltzmann modelling process.

FIGS. 2A-2B show examples of lattice Boltzmann operations in a two-dimensional discretized space.

FIG. 3 shows an example of a volume-based lattice Boltzmann modelling process with grid refinement.

FIG. 4 shows an example of a lattice Boltzmann modelling process with optimized grid refinement implementation.

FIG. 5 shows a flowchart of an example of a lattice Boltzmann modelling process with optimized grid refinement implementation.

FIGS. 6A-6D show examples of lattice Boltzmann modelling processes with optimized grid refinement implementation and kernel fusion.

FIG. 7 shows an example of a data structure for lattice Boltzmann modelling processes implementation.

FIG. 8 shows a flowchart of an example of a lattice Boltzmann modelling process optimized for GPU implementation.

FIG. 9A shows an example of a simulation performed with a lattice Boltzmann modelling process with optimized grid refinement.

FIG. 9B shows a comparison of memory use of different implementations of a lattice Boltzmann modelling process.

FIG. 10 is a schematic diagram of a data processing system including a data processing apparatus, which can be programmed as a client or as a server, and implement the techniques described in this document.

Like reference numbers and designations in the various drawings indicate like elements.

### DETAILED DESCRIPTION

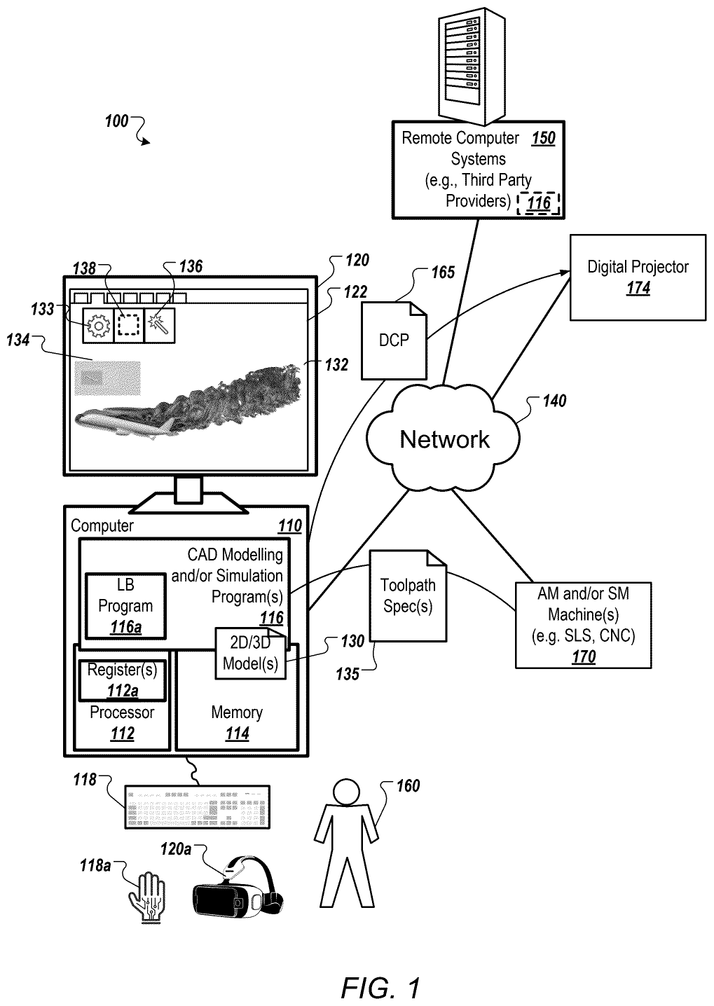

FIG. 1 shows an example of a system 100 usable to facilitate implementation of the described memory management techniques in a lattice Boltzmann modelling process. A computer 110 includes a processor 112 and a memory 114, and the computer 110 can be connected to a network 140, which can be a private network, a public network, a virtual private network, etc. The processor 112 can be one or more hardware processors, which can each include multiple processor cores. The memory 114 can include both volatile and non-volatile memory, such as Random Access Memory (RAM) and Flash RAM. The computer 110 can include various types of computer storage media and devices, which can include the memory 114, to store instructions of programs that run on the processor 112, including CAD modelling and/or simulation program(s) 116, which include a program 116a, such as a lattice Boltzmann (LB) program that includes efficient encoding/decoding of boundary conditions in a lattice Boltzmann modelling process as described.

In some instances, numerical simulation performed by the systems and techniques described in this document can simulate one or more physical properties to produce a numerical assessment of a physical response of a modeled object. Further, the simulation of physical properties can include Computational Fluid Dynamics (CFD), Acoustics/Noise Control, thermal conduction, computational injection molding, electric or electro-magnetic flux, and/or material solidification (which is useful for phase changes in molding processes) simulations.

As used herein, CAD refers to any suitable program used to design physical structures that meet design requirements, regardless of whether or not the program is capable of interfacing with and/or controlling manufacturing equipment. Thus, CAD program(s) 116 can include Computer Aided Engineering (CAE) program(s), Computer Aided Manufacturing (CAM) program(s), etc. The program(s) 116 can run locally on computer 110, remotely on a computer of one or more remote computer systems 150 (e.g., one or more third party providers' one or more server systems accessible by the computer 110 via the network 140) or both locally and remotely. Thus, a program 116 can be two or more programs that operate cooperatively on two or more separate computer processors in that one or more programs 116 operating locally at computer 110 can offload processing operations (e.g., lattice Boltzmann modelling and/or physical simulation operations) “to the cloud” by having one or more programs 116 on one or more computers 150 perform the offloaded processing operations. In some implementations, all lattice Boltzmann modelling and/or simulation operations are run by one or more programs in the cloud and not in a geometry representation modeler that runs on the local computer. Moreover, in some implementations, the lattice Boltzmann modelling and/or simulation program(s) can be run in the cloud from an Application Program Interface (API) that is called by a program, without user input through a graphical user interface.

The CAD modelling and simulation program(s) 116 present a user interface (UI) 122 on a display device 120 of the computer 110, which can be operated using one or more input devices 118 of the computer 110 (e.g., keyboard and mouse). Note that while shown as separate devices in FIG. 1, the display device 120 and/or input devices 118 can also be integrated with each other and/or with the computer 110, such as in a tablet computer (e.g., a touch screen can be an input/output device 118, 120). Moreover, the computer 110 can include or be part of a virtual reality (VR) and/or augmented reality (AR) system. For example, the input/output devices 118, and 120 can include VR/AR input controllers, gloves, or other hand manipulating tools 118a, and/or a VR/AR headset 120a. In some instances, the input/output devices can include hand-tracking devices that are based on sensors that track movement and recreate interaction as if performed with a physical input device. In some implementations, VR and/or AR devices can be standalone devices that may not need to be connected to the computer 110. The VR and/or AR devices can be standalone devices that have processing capabilities and/or an integrated computer such as the computer 110, for example, with input/output hardware components such as controllers, sensors, detectors, etc.

In any case, a user 160 can interact with the program(s) 116 to generate and/or optimize 3D model(s), which can be stored in model document(s) 130. The user 160 can interact with program 116a to perform lattice Boltzmann modelling processes as described. In the example shown in FIG. 1, a 2D or a 3D model 132 includes a discretized space 134 including lattice units to perform a lattice Boltzmann modelling process.

The user or a program can set up 133 the lattice Boltzmann modelling process. For example, the user or a program can select 133 a CPU (Central Processing Unit) or a GPU (Graphics Processing Unit) implementation. The user or a program can select 133 using single GPU or multiple GPUs. The user or a program can select 136 whether to use kernel fusion. Kernel fusion (or loop fusion) is an optimization technique commonly employed in high-performance computing. Kernel fusion combines multiple tasks or “kernels” into a single kernel. This reduces kernel launch overhead and potentially also the number of load and store memory operations. Kernel fusion can merge into a single computational kernel several stages of the lattice Boltzmann algorithm. As a result, a fused lattice Boltzmann kernel can reduce the number of load and store memory operations per iteration. A user or a program can select 138 one or more boundary conditions (e.g., Zou-He boundary conditions, no slip, etc.) for some of the lattice units at boundaries of the discretized space 134.

The lattice Boltzmann modelling or simulation process can be used to perform a simulation of a physical structure. For example, the lattice Boltzmann process can be used to perform a computational fluid dynamics simulation to optimize the physical structure design to meet physical design requirements. The resulting computer model 132 can be used to generate control instructions for manufacturing the physical structure using a manufacturing machine. Once the lattice Boltzmann modelling or simulation process has finished and the user 160 is satisfied with the result, the computer model 132 can be stored as a model document 130 and/or used to generate another representation of the model (e.g., toolpath specifications for a manufacturing process for the structure or portions thereof). This can be done upon request by the user 160, or in light of the user's request for another action, such as sending the computer model 132 to a manufacturing machine, e.g., additive manufacturing (AM) machine(s) and/or subtractive manufacturing (SM) machine(s) 170, or other manufacturing machinery, which can be directly connected to the computer 110, or connected via a network 140, as shown. This can involve a post-process carried out on the local computer 110 or externally, for example, based on invoking a cloud service running in the cloud, to further process the computer model (e.g., based on considerations associated with the additive manufacturing process) and to export the computer model to an electronic document from which to manufacture. Note that an electronic document (which for brevity will simply be referred to as a document) can be a file, but does not necessarily correspond to a file. A document may be stored in a portion of a file that holds other documents, in a single file dedicated to the document in question, or in multiple coordinated files. In addition, the user 160 can save or transmit the computer model for later use. For example, the program(s) 116 can store the document 130 that includes model 132.

The program(s) 116 can provide a document 135 (e.g., having toolpath specifications of an appropriate format) to an AM and/or SM machine 170 to produce a physical structure corresponding to at least a portion of the model 132. An AM machine 170 can employ one or more additive manufacturing techniques, such as granular techniques (e.g., Powder Bed Fusion (PBF), Selective Laser Sintering (SLS) and Direct Metal Laser Sintering (DMLS)) or extrusion techniques (e.g., Fused Filament Fabrication (FFF), metals deposition). In some cases, the AM machine 170 builds the designed object directly. In some cases, the AM machine 170 builds a mold for use in casting or forging the designed object.

A SM machine 170 can be a Computer Numerical Control (CNC) milling machine, such as a multi-axis, multi-tool milling machine used in the manufacturing process. For example, the CAD program(s) 116 can generate CNC instructions for a machine tool system 170 that includes multiple tools (e.g., solid carbide round tools of different sizes and shapes, and insert tools of different sizes that receive metal inserts to create different cutting surfaces) useable for various machining operations. Thus, in some implementations, the CAD program(s) 116 can provide a corresponding document 135 (having toolpath specifications of an appropriate format, e.g., a CNC numerical control (NC) program) to the SM machine 170 for use in manufacturing the physical structure using various cutting tools, etc.

In addition, in some implementation, no physical manufacturing is involved. The systems and techniques described herein are applicable to any suitable 3D modelling software. Thus, in some implementations, the program(s) 116 can be animation production program(s) that render the model 132 to a document 165 of an appropriate format for visual display, such as by a digital projector 174 (e.g., a digital cinema package (DCP) 165 for movie distribution) or other high resolution display device. Other applications are also possible.

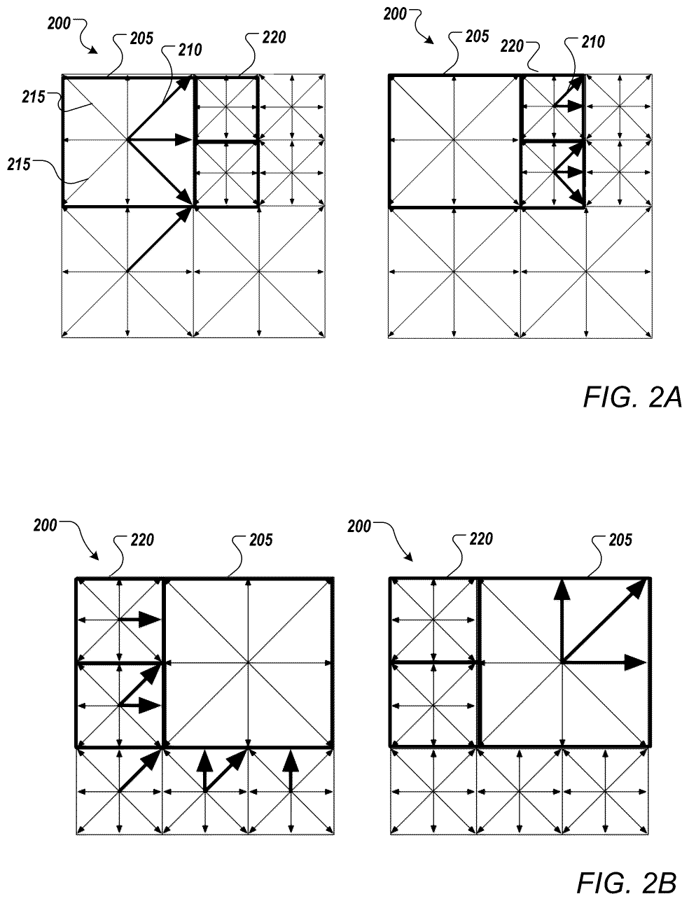

FIGS. 2A-2B show examples of lattice Boltzmann operations in a two-dimensional discretized space with grid refinement. The discretized space includes a lattice structure 200 with lattice units or cells 205, 220 of two different sizes. Cells 205 correspond to a level of refinement L=0 (coarsest level) while cells 220 correspond to a subsequent level of refinement L=1. In the example, the refinement ratio is 2^{d}. A cell 205 at level L is uniformly divided into 2^{d} cells, where d is the dimension (d=2 in this case), to arrive at level L+1. In other words, Δx_{L}+1=Δx_{L}/2. In some examples, for neighboring cells that interface two grid levels, a maximum change in grid level of L=1 is allowed. Due to acoustic scaling, which requires the speed of sound to remain constant across various grid levels, Δt_{L} is proportional to Δx_{L} and Δt_{L+1}=Δt_{L}/2 The fluid viscosity also remains constant across all grid levels.

The lattice Boltzmann equations determine the time-evolution of a collection of fictitious particles in a lattice structure 200. The collection of fictitious particles can be represented by velocity distributions 210 (also known as time-dependent velocity distribution functions) ƒᵢ along a set of q discrete lattice directions 215 denoted by eᵢ=(e₁, . . . , e_{q}). For example, 3D lattice structures with q=19 (D3Q19) or q=27(D3Q27) directions can be used. Fluid density, velocity, and pressure can be formally derived from the velocity distributions.

During a lattice Boltzmann simulation, the values of the velocity distributions 210 are evolved in time. For example, an algorithm that performs a series of a collision and streaming operations can be used. During the collision operation, particles interact with each other and their distribution function is updated to obtain a post-collision velocity distribution ƒ* based on a collision operator C as ƒᵢ*=C(ƒᵢ(x, t)). Different collision operators can be used. For example, the single-relaxation collision model of Bhatnagar-Gross-Krook (BGK) or the multi-relaxation entropic model of Karlin-Bösch-Chikatamarla (KBC) can be used. During the streaming operation, particles propagate along the lattice directions 215 and the velocity distributions 210 are updated accordingly, either by pulling the velocity distribution values from neighbouring cells, which requires remote reads and local writes, or by pushing velocity distribution information to neighbouring cells, which requires local reads and remote writes. In the latter case, the operation reads ƒᵢ(x+eᵢΔx, t+Δt)=ƒᵢ*(x, t).

When implementing grid refinement in the lattice Boltzmann method, velocity distribution information is communicated among the different refinement levels, including coarse-to-fine communication and fine-to-coarse communication. Grid-refinement can be implemented as a node-based method or as a volume-based method. In node-based methods, the distribution functions are stored at the nodes of the lattice structure. This leads to shared vertices between cells of different levels of refinement. In order to impose conservation of mass and preserve second-order accuracy, node-based methods often resort to scheme-dependent rescaling of the velocity distributions across transitions between refinement levels and rely on ad hoc interpolation and filtering schemes that may lead to spurious results. In contrast, in volume-based techniques the distribution functions are stored at the cells, rather than at the nodes. Velocity distributions of two subsequent grid levels (e.g., grid cell 205 and grid cell 220 in FIGS. 2A and 2B) are not collocated but staggered. This renders the communication between coarse and fine levels more straightforward. In volume-based methods, a homogeneous redistribution of the velocity distributions can be used as an interpolation scheme for coarse-to-fine communications while conserving mass and momentum.

A coarse-to-fine communication operation or “explosion” operation is shown in FIG. 2A. In some examples, the explosion operation corresponds to a homogeneous redistribution of the distribution functions 210 of the coarse level ƒᵢ(xₐ, L, t) to the distribution functions ƒᵢ(x_{b}, L+1, t) of a finer level, such that ƒᵢ(x_{b}, L+1, t)=ƒᵢ(xₐ, L, t). A fine-to-coarse communication operation or “coalescence” operation is shown in FIG. 2B. In some examples, the coalescence operation corresponds to an averaging of the distribution functions ƒᵢ(x_{b}, L+1) across n fine cells 220 that interface with a coarse cell 205 to obtain the distribution function of the coarse cell ƒᵢ (xₐ, L, t) 210, such that

$${f}_{i} ( {x}_{a} , L , t ) = ( \frac{1}{n} ) {\sum }_{β = I}^{n} {f}_{i} ( {x}_{b} , L + 1 , t ) .$$

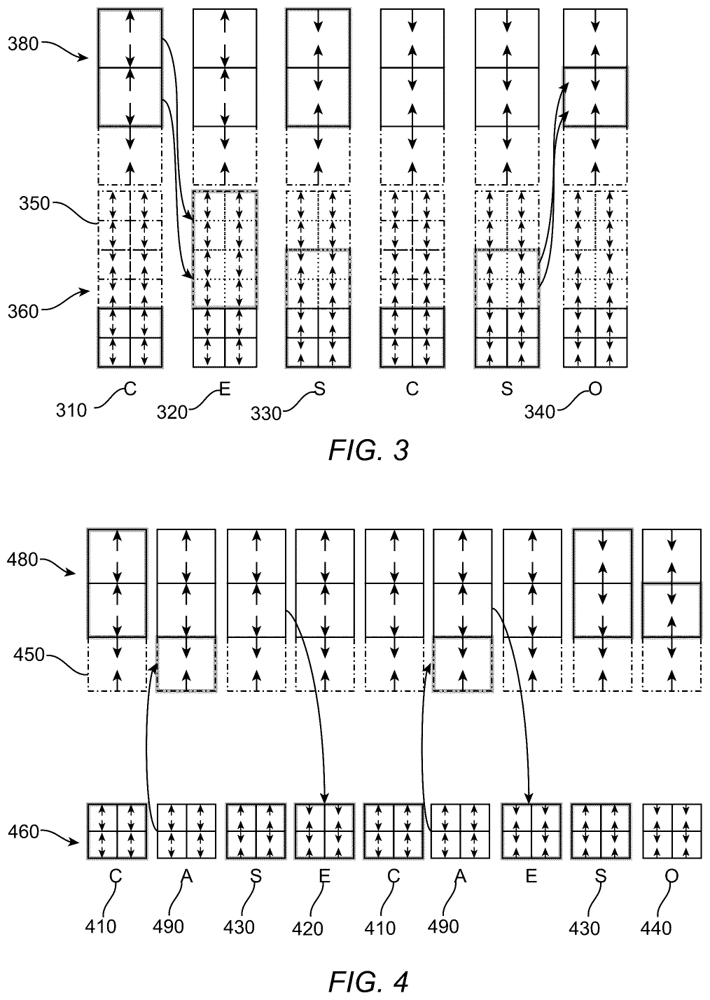

FIG. 3 is an example of a volume-based lattice Boltzmann modelling process with grid refinement including collision 310 (C), streaming 330 (S), explosion 320 (E), and coalescence 340 (O) operations. The collision operation 310 computes the post-collision distribution ƒᵢ* as described above, similar to a uniform lattice Boltzmann algorithm. Since this operation involves only local computations and does not require any communications with other cells, it is not impacted by grid refinement. The streaming operation 330 among cells belonging to the same level of refinement (called streaming hereinafter) propagates the information in time and space by conducting a shift operation as described above. Further, the algorithm includes coalesce 340 and explosion 320 operations for interlevel communication. The explosion operation 320 performs coarse-to-fine communication to propagate the distribution functions from a coarse neighboring cell into finer cells as described above. Explosion is a one-to-many communication where a coarse cell distributes its values of the distribution function along a lattice direction eᵢ to finer cells that interface with that coarse cell along lattice direction −eᵢ, as shown in FIG. 2A. The coalescence operation 340 performs fine-to-coarse communications to propagate the distribution functions from fine neighboring cells into coarse cells, as described above. Coalescence is a many-to-one communication where a coarse cell averages the contributions of the distribution functions from neighboring fine cells along a certain eᵢ lattice direction, as shown in FIG. 2B.

The algorithm shown in FIG. 3 applies the standard lattice Boltzmann collision and streaming algorithm at each level starting from the coarsest level. However, during the streaming operation, the interface between different levels requires special treatment. This is where the uniform versus nonuniform (i.e., with grid refinement) algorithm differs. Additionally, for a refinement ratio of two between levels L and L+1, the algorithm completes two time-steps at level L+1 before proceeding to the next time step of the coarse level due to the acoustic scaling. In other words, given a grid with L levels, the finest grid perform 2^{L-1} time steps to complete one time step on the coarsest level.

To facilitate the communication between different levels of the grid, the interface between a grid at level L and a finer neighbor at level L+1 is extended by a ghost layer 350 which lives in the finer L+1 grid 360 and covers two coarser layers from the grid at level L 380. These ghost layers can be used for communicating interface information both ways, i.e., from coarse to fine and from fine to coarse. All the reads/writes can be done as a gather or scatter operation without the need for any atomic mechanism thanks to these added ghost layers.

A pseudocode for a single time step of the coarsest level is shown below for a grid with any number of refinement levels. This step can be repeated in a loop until a user-specified (or predefined) stopping criterion is met, e.g., based on the maximum number of iterations. For a two-level grid with levels L (coarse) and L+1 (fine), the algorithm for the single time step starts from a post-streaming state and performs a collision operation 310 on L and L+1. Then, an explosion operation 320 populates the ghost layers of level L+1 by copying two layers of L along the interface between L and L+1. This is followed by a streaming operation 330 in L and L+1, including the innermost layer of the ghost cells. Then, additional collision and streaming operations are performed on L+1. Finally, a coalescence operation 340 is performed. The innermost ghost layer populations in L+1 are averaged and copied to the overlapping corresponding coarse cells in L. A drawback of implementing this algorithm in on the GPU is that every operation is performed in isolation-missing the opportunity for kernel fusion. This leads to loading the whole grid multiple times to operate only on a small subset of it, e.g., during the explosion and coalescence operations that operate only on the interface between coarse and fine levels.

Algorithm 1: Baseline Grid Refinement LBM Algorithm

```
Function NonUniformTimeStep (L):
  Collision (L)
  if L ≠ L_{maz} − 1 then
  | NonUniformTimeStep (L + 1)
  end
  if L ≠ 0 then
  | Explosion (L, L − 1)
  end
  Streaming (L)
  if L ≠ L_{maz} − 1 then
  | Coalescence (L, L + 1)
  end
  if L == 0 then
  | return
  end
  Collision (L)
  if L ≠ Lmaz − 1 then
  | NonUniformTimeStep (L + 1)
  end
  if L ≠ 0 then
    | Explosion (L, L − 1)
    end
    Streaming (L)
    if L ≠ L_{maz} − 1 then
    | Coalescence (L, L + 1)
    end
```

Further, this algorithm uses four ghost layers on the fine grid which overlap two coarse layers. These ghost layers are employed to duplicate the overlapping coarse layers to leverage the two innermost layers of the ghost layers during the streaming operation of the fine level. The fine ghost layers also allow the coalescence operation to be performed as a gather operation initiated by the coarse layer, avoiding atomic operations. However, this approach is only reasonable if the distance in memory between the fine and coarse grid is large. On a single GPU, four ghost layers are excessive and may limit the maximum size of the problem that ƒits in a single GPU. Additionally, depending on the data structure used, the distance between grids at different resolutions may not be large enough to warrant manual caching.

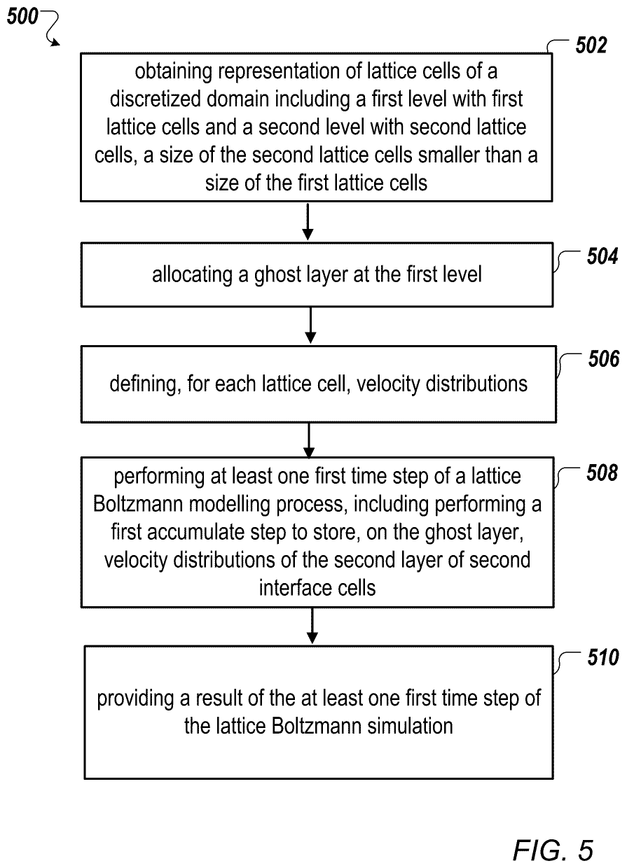

FIG. 4 shows an example of a volume-based lattice Boltzmann modelling process with optimized grid refinement implementation. Instead of allocating the ghost layer on the fine level, a ghost layer 450 is allocated on the coarse level. For example, a single ghost layer on the coarse layer can be allocated, effectively reducing the size of the ghost layer to ⅓ of what is needed in the non-GPU optimized implementation. The process of FIG. 4 is also a collision and streaming algorithm that includes collision operations 410 and streaming operations 430 as well as explosion operations 420 and a coalescence operation 440. In this case, during the explosion operation 420 (i.e., coarse to-fine communication), the fine grid 460 can read directly from the coarse grid 480. This ghost layer 450 on the coarse grid 480 can be used to prepare the information needed by the interface cells of the coarse grid 480. This approach turns the coalescence operation 440 into a streaming-like operation, as shown in FIG. 4. As a result, a coalescence operation 440 can be split into two operations: an accumulate operation 490 on the ghost layer after a fine-level collision operation 410, and a coalescence operation 440 by the coarse level to read and average the accumulated information.

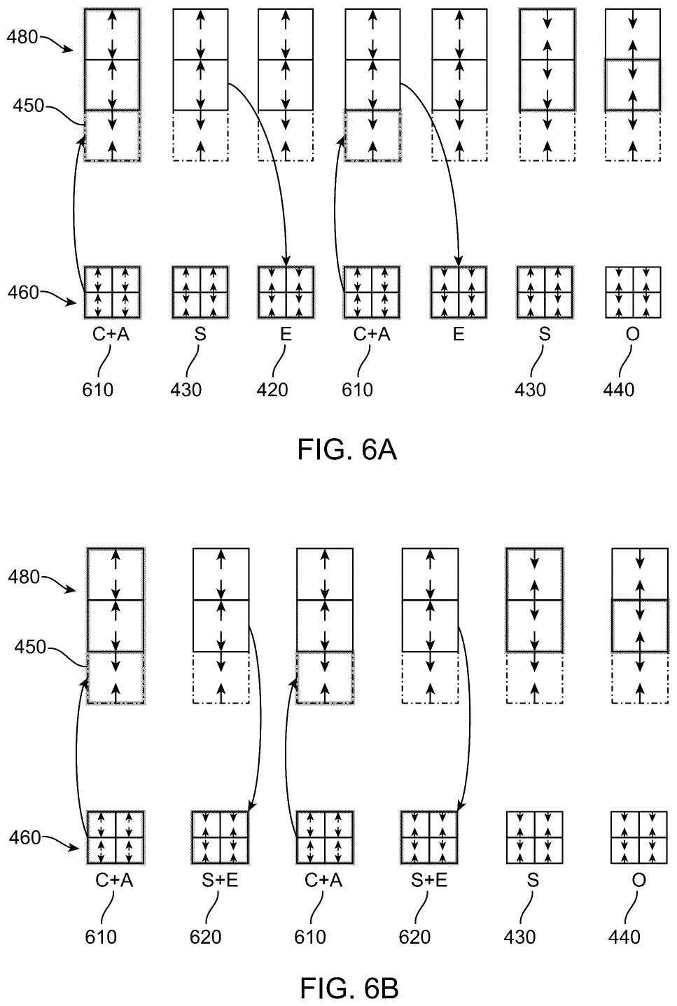

FIG. 5 is a flowchart of an example of a lattice Boltzmann modelling process with optimized grid refinement implementation. The method 500 includes obtaining 502 a representation of lattice cells of a discretized domain. The discretized domain can include a first level (e.g., the coarse grid 480) comprising first lattice cells and a second level (e.g., the fine grid 460) comprising second lattice cells. The size of the second lattice cells of the second level is smaller than the size of the first lattice cells of the first level. The first lattice cells include a first layer of first interface lattice cells and the second lattice cells comprise a second layer of second interface lattice cells. The first interface lattice cells and the second interface lattice cells are neighboring cells at an interface between the first level and the second level.

At 504, a ghost layer 450 can be allocated at the first level. The ghost layer can include a layer of first ghost lattice cells adjacent to the first layer of first interface lattice cells and overlapping the second layer of second interface cells. Allocating the ghost layer can include allocating the ghost layer in a shared memory that is accessed by a single hardware processor, such as a single GPU or a single CPU. The shared memory can be a memory shared by two or more processing threads that run on the single hardware processor concurrently (e.g., in parallel). The shared memory can be a thread register of a GPU. The shared memory can be a local memory. A local memory can be a memory that is close enough to a processor of a processing system so that the memory is connected to a system bus of an integrated circuit chip on or in which the processor is built. The local memory can be a register memory or a cache memory of the processing system.

At 506, for each lattice cell, velocity distributions can be defined along lattice directions corresponding to each of a predetermined number of lattice vectors eᵢ such as described above. As described above, the lattice vectors are associated with a number q of different lattice directions.

At 508, at least one first time step of a lattice Boltzmann modelling process is performed. Performing the at least one first time step can include performing a first accumulate operation 490 as shown in FIG. 4 to store, on the ghost layer 450, velocity distributions of the second layer of second interface cells.

The accumulate operation 490 is similar to the coarse-level coalescence 340 in the algorithm of FIG. 3 but without division (Σ_{β=1}ⁿƒᵢ(x_{b}, L+1, t)). The division to average the data

$$( {f}_{i} ( {x}_{a} , L , t ) = ( \frac{1}{n} ) {\sum }_{β = I}^{n} {f}_{i} ( {x}_{b} , L + 1 , t ) )$$

is done during the coalescence operation 440 on the coarse level. The accumulate operation 490 can be performed either as a gather read operation from the ghost layer or as a scatter atomic write operation from the fine level. As in this case every ghost cell can be written by a maximum of 8 other fine cells, the differences in computational costs are not very high. In the example of FIG. 4, after two accumulate operations 490, the information is ready for the coarse layer to do its coalescence operation 440.

At 510, a result of the at least one first time step of the lattice Boltzmann simulation can be provided. In some examples, the lattice Boltzmann modelling process can be used in a computational fluid dynamics process. The provided result can include a fluid density evolution in the discretized space. As described with reference to FIG. 1, providing a result of the at least one time step of the lattice Boltzmann modelling process can include storing the computer model 132 including discretized space 134 as a model document 130 and/or using it to generate another representation of the model (e.g., toolpath specifications for a manufacturing process for a structure or portions thereof) and/or providing it as a digital asset, such as for use in animation.

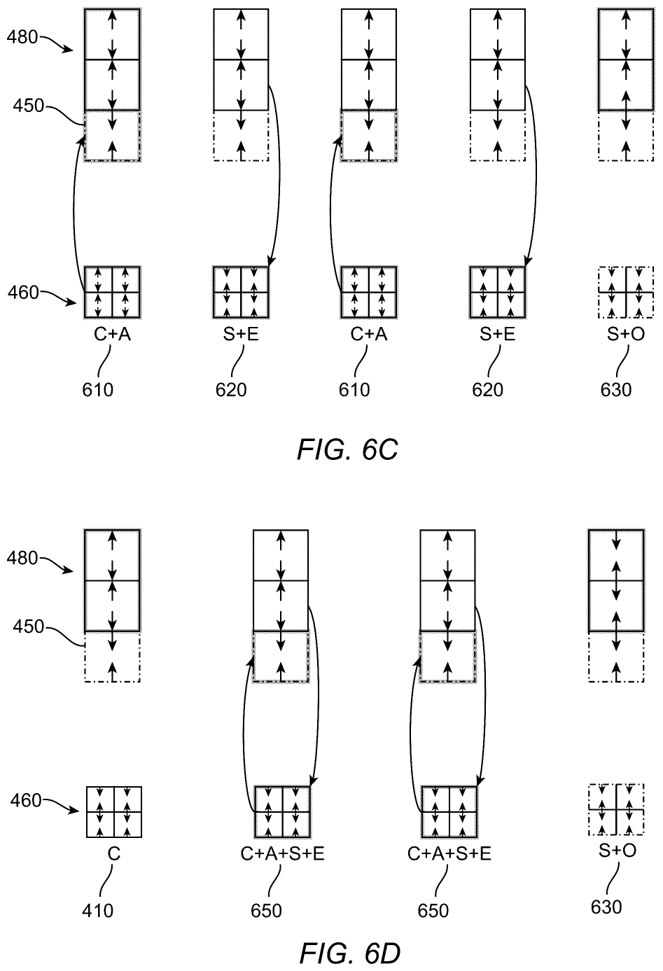

FIGS. 6A-6D show examples of lattice Boltzmann modelling processes with optimized grid refinement implementation and kernel fusion. Thanks to the improvements to the grid refinement implementation, kernel fusion can be more fully employed. In particular, performing the accumulate operation 440 as an atomic write opens the door for several kernel fusion options. If the accumulate operation 440 were done as a gather operation by the coarse cell, the data dependency would not allow kernel fusion since the coarse level should wait for the fine level to finish its collision operation 410 before performing the accumulate operation 440.

For example, as shown in FIG. 6A, the collision and accumulate operations can be fused together 610 in a single kernel (C+A). In this kernel, every cell can perform its collision operations. If the cell is a fine interface cell that interfaces with a coarse cell, it accumulates its velocity distributions. The velocity distributions can be stored in a shared memory that is accessed by a single hardware processor, such as registers of the processing unit. When the coarse cell performs its coalescence operation 440, it resets the ghost layer 450. This allows subsequent accumulate operations to be performed correctly.

Additionally or alternatively, the explosion and streaming operations can also be fused since in this algorithm the explosion is a sub-operation of the streaming operation where the missing distribution functions live on a grid of different resolution. FIG. 6B shows an example where both the collision and accumulate are fused 610 in a kernel (C+A) and the explosion and streaming operations are fused 620 in another kernel (S+E).

Additionally or alternatively, the coalescence and streaming operations can also be fused 630 in a single kernel (S+O) since in this algorithm the coalescence is a sub-operation of the streaming operation where the missing distribution functions live on a grid of different resolution. FIG. 6C shows an example where the collision and accumulate are fused 610 in a kernel, the explosion and streaming operations are fused 620 in another kernel, and the coalescence and streaming operations are also fused 630 in a single kernel. When there are more than two levels, the middle level can fuse the streaming, explosion, and coalescence operations all in one kernel.

Similar to the uniform (i.e., without grid refinement) lattice Boltzmann algorithm, the collision and streaming operations can additionally be fused 650 in one kernel (C+A+S+E) for the finest resolution, as shown in FIG. 6D. Since the majority of the computation is done on the finest level, this fusion is expected to be extremely beneficial. Unlike a uniform lattice Boltzmann algorithm, the kernel fusion of FIG. 6D also requires the collision and streaming operations to perform the accumulate and explosion operations respectively.

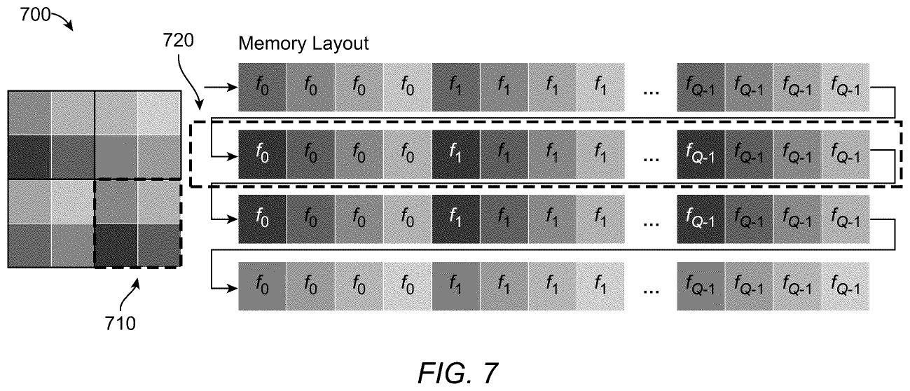

FIG. 7 shows an example of a data structure for lattice Boltzmann modelling processes implementation. There are two main approaches for designing data structure for lattice Boltzmann simulations: a forest of octrees or a stack of uniform sparse grids. Each can support LBM single-level operations, with some strategy to transition between different levels aimed at supporting multilevel operations. However, since the majority of the work occurs on the finest level, a stack of uniform sparse grids can have superior performance compared to an octree structure. Most of the operations involved are stencil operations which can be handled better by a uniform grid rather than a tree traversal.

The described techniques can use a sparse grid as the basis for the data structure. The input domain 700 can be partitioned into 2D or 3D blocks 710 of fixed size. The blocks can be placed in active regions associated with a fluid domain. For each block, a bitmask can be allocated to track active cells within the block. Additionally, the indices of all the neighboring blocks in all lattice directions (e.g., 26 directions for D3Q27) can be stored to be used for stencil operations. Given a cell, its intra-block and inter-block neighbor cells can be identified via division and modulo operations either using inexpensive bit operations (for intra-block neighbors) or explicitly (for inter-block neighbors).

The block size is known at compile time which allows for various optimizations. To maximize locality, at runtime, a block can be assigned to one thread block or thread group (e.g., a CUDA block) including group threads that use a same portion of the shared memory. Every group thread (e.g., a CUDA thread) is assigned to a cell within the given block. To represent vector fields over a grid (e.g., the 19-component vector field for D3Q19 velocity distributions), an Array of Structures of Arrays (AoSoA) layout as shown in FIG. 7 can be used. Block's field data can be stored in a contiguous memory region 720, where data is then grouped by field's component. The memory layout and the mapping to thread blocks guarantee coalesced accesses and maximize memory locality within a block. To improve the data locality between blocks, blocks can be arranged in memory using space-filling curves (e.g., Sweep, Morton, or Hilbert).

The grid refinement data structure can be implemented by stacking Lₘₐₓ (maximum refinement level) block sparse data structures. In some examples, the block data structure can be extended with information to allow access to neighbor interface cells at a different resolution. For example, for a grid at level L, the block index of an overlapping ghost block at level L−1 can be stored.

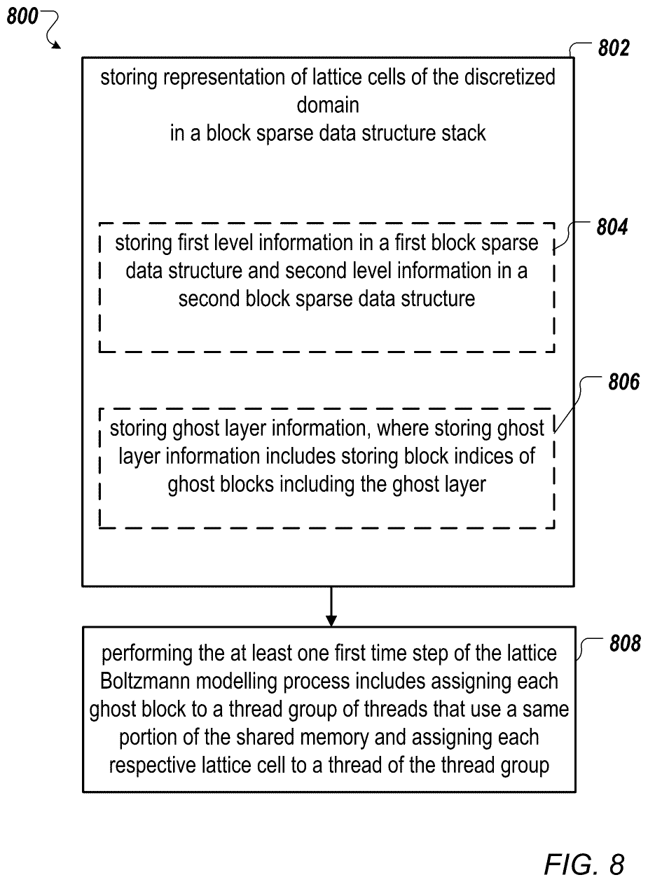

FIG. 8 shows a flowchart of an example of a method 800 of a lattice Boltzmann modelling process using a data structure such as a block sparse data structure stack. The method can include storing 802 the representation of lattice cells of the discretized domain in a block sparse data structure stack.

Storing 802 the representation of lattice cells of the discretized domain in the block sparse data structure stack can include storing 804 first level information in a first block sparse data structure and second level information in a second block sparse data structure. Each first block of the first block sparse data structure can include respective first cells and each second block of the second block sparse data structure comprises respective second cells. Storing 802 the representation of lattice cells of the discretized domain in the block sparse data structure stack can also include storing 806 ghost layer information, wherein storing ghost layer information comprises storing block indices of ghost blocks comprising the ghost layer.

The method 800 also includes performing 808 at least one first time step of the lattice Boltzmann modelling process. Performing 808 the at least one first time step of the lattice Boltzmann modelling process includes assigning each ghost block to a thread group comprising threads that use a same portion of the shared memory and assigning each respective lattice cell to a thread of the thread group.

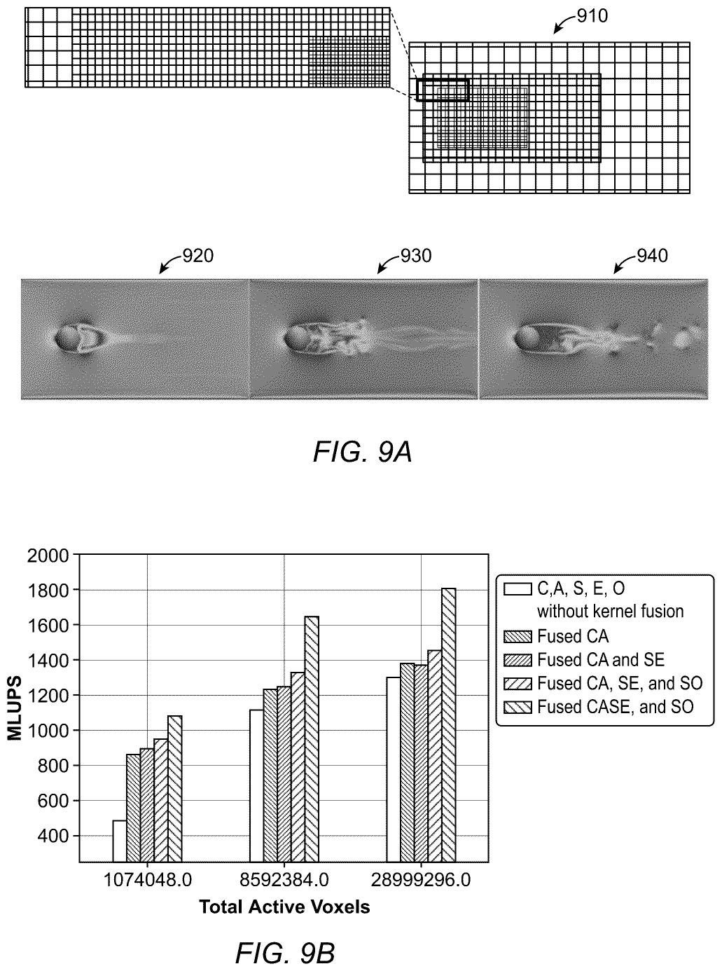

FIG. 9A shows an example of a simulation performed with a lattice Boltzmann modelling process with optimized grid refinement. FIG. 9B shows a comparison of memory use of different implementations of a lattice Boltzmann modelling process for the same simulation. The simulation of FIGS. 9A and 9B is a simulation of flow over a sphere in a virtual wind tunnel. FIG. 9A shows a grid 910 with three levels of refinement around the sphere. FIG. 9A also shows the evolution of the flow over the sphere at different iteration snapshots. The flow over the sphere at 5000 iterations 920, at 10000 iterations 930, and at 30000 iterations 940 is shown. No-slip boundary conditions can be imposed on the side walls and on the sphere. For example, the halfway bounce-back method can be used. The inlet velocity associated with the incoming flow inside the wind tunnel can also be prescribed using the same bounce-back technique.

FIG. 9B shows the number of million lattice updates per second (MLUPS) for the different optimizations. The MLUPS are calculated as a function of the Lₘₐₓ number of levels of the multi-resolution grid, the number of active voxels or units of a 3D discretized domain at level L excluding any ghost cells, and the wall-clock time (e.g., in microseconds) to complete N_{L} iterations on level L (N_{L}=N2^{L}). FIG. 9B shows that the fusion of collision and streaming operations associated with the finest resolution has the largest contribution to the speedup, since the voxels at the finest resolution consume more than half of the number of active voxels. This fusion is only possible thanks to the introduction of the accumulate operation which breaks the data dependency allowing the finest level to fuse the collision and streaming operations into one.

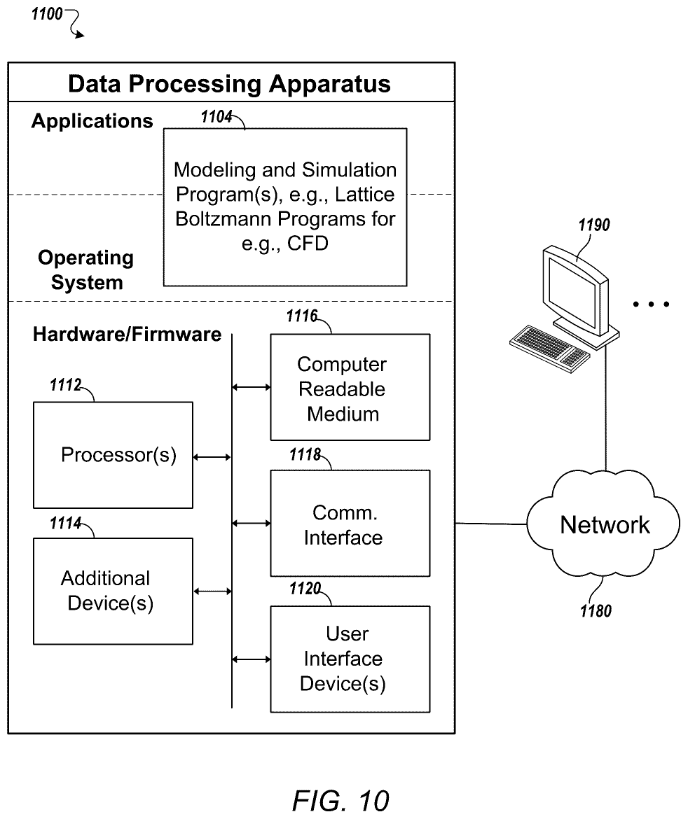

FIG. 10 is a schematic diagram of a data processing system including a data processing apparatus 1100, which can be programmed as a client or as a server. The data processing apparatus 1100 is connected with one or more computers 1190 through a network 1180. While only one computer is shown in FIG. 10 as the data processing apparatus 1100, multiple computers can be used. The data processing apparatus 1100 includes various software modules, which can be distributed between an applications layer and an operating system. These can include executable and/or interpretable software programs or libraries, including tools and services of one or more programs 1104, as described above. Thus, the modeling and simulation program(s) 1104 can be program(s) 1104 for lattice Boltzmann modeling processes (such as program(s) 116) for e.g., computational fluid dynamics and can implement grid refinement in a GPU-optimized (e.g., in a single GPU) manner, as described. Further, the program(s) 1104 can potentially implement manufacturing control operations (e.g., generating and/or applying toolpath specifications to effect manufacturing of designed objects). The number of software modules used can vary from one implementation to another. Moreover, the software modules can be distributed on one or more data processing apparatus connected by one or more computer networks or other suitable communication networks.

The data processing apparatus 1100 also includes hardware or firmware devices including one or more processors 1112, one or more additional devices 1114, a computer readable medium 1116, a communication interface 1118, and one or more user interface devices 1120. Each processor 1112 is capable of processing instructions for execution within the data processing apparatus 1100. In some implementations, the processor 1112 is a single or multi-threaded processor. Each processor 1112 is capable of processing instructions stored on the computer readable medium 1116 or on a storage device such as one of the additional devices 1114. The data processing apparatus 1100 uses the communication interface 1120 to communicate with one or more computers 1190, for example, over the network 1180. Examples of user interface devices 1120 include a display, a camera, a speaker, a microphone, a tactile feedback device, a keyboard, a mouse, and VR and/or AR equipment. The data processing apparatus 1100 can store instructions that implement operations associated with the program(s) described above, for example, on the computer readable medium 1116 or one or more additional devices 1114, for example, one or more of a hard disk device, an optical disk device, a tape device, and a solid state memory device.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as hard drive in a computer system or an optical disc sold through retail channels, or an embedded system. The computer-readable medium can be acquired separately and later encoded with the one or more modules of computer program instructions, e.g., after delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any suitable form of programming language, including compiled or interpreted languages, declarative or procedural languages, and it can be deployed in any suitable form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, subprograms, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., an LCD (liquid crystal display) display device, an OLED (organic light emitting diode) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any suitable form of sensory feedback, e.g., visual feedback, auditory feedback, or tactile feedback; and input from the user can be received in any suitable form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a backend component, e.g., as a data server, or that includes a middleware component, e.g., an application server, or that includes a frontend component, e.g., a client computer having a graphical user interface or a browser user interface through which a user can interact with an implementation of the subject matter described is this specification, or any combination of one or more such backend, middleware, or frontend components. The components of the system can be interconnected by any suitable form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. In addition, actions recited in the claims can be performed in a different order and still achieve desirable results.

What is claimed is:

1. A method comprising:
obtaining a representation of lattice cells of a discretized domain, wherein the discretized domain comprises a first level comprising first lattice cells and a second level comprising second lattice cells, wherein a size of the second lattice cells is smaller than a size of the first lattice cells, wherein the first lattice cells comprise a first layer of first interface lattice cells and the second lattice cells comprise a second layer of second interface lattice cells, wherein the first interface lattice cells and the second interface lattice cells are neighboring cells at an interface between the first level and the second level;
allocating a ghost layer at the first level, wherein the ghost layer comprises a layer of first ghost lattice cells adjacent to the first layer of first interface lattice cells and overlapping the second layer of second interface cells, wherein allocating the ghost layer comprises allocating the ghost layer in a shared memory that is accessed by a single hardware processor;
defining, for each lattice cell, velocity distributions along lattice directions corresponding to each of a predetermined number of lattice vectors associated with different lattice directions;
performing at least one first time step of a lattice Boltzmann modelling process, wherein performing the at least one first time step comprises performing a first accumulate operation to store, on the ghost layer, velocity distributions of the second layer of second interface cells; and
providing a result of the at least one first time step of the lattice Boltzmann simulation.

2. The method of claim 1, wherein performing the at least one first time step of the lattice Boltzmann modelling process further comprises
performing a first first-level collision operation on the first level to update velocity distributions of the first level,
performing a first second-level collision operation on the second level to update velocity distributions of the second level,
performing an explosion operation to populate velocity distributions of the second layer of second interface cells using velocity distributions of the first level,
performing a first first-level streaming operation on the first level to update velocity distributions of the first level,
performing a first second-level streaming operation on the second level to update velocity distributions of the second level,
performing a second second-level collision operation on the second level to update velocity distributions of the second level,
performing a second accumulate operation to store, on the ghost layer, the velocity distributions of the second layer of second interface cells,
performing a second second-level streaming operation on the second level to update the velocity distributions of the second level, and
performing a coalesce operation, wherein performing the coalesce operation comprises reading and averaging the velocity distributions stored on the ghost layer to update velocity distributions of the first level.

3. The method of claim 2, wherein the collision operations and the accumulate operations are executed in a single computational kernel, wherein the accumulate operations are performed as atomic writes.

4. The method of claim 2, wherein the explosion operations and the streaming operations are executed in a single computational kernel.

5. The method of claim 2, wherein the coalescence operations and the streaming operations are executed in a single computational kernel.

6. The method of claim 2, wherein the collision operations and the streaming operations are executed in a single computational kernel.

7. The method of claim 1, further comprising
storing the representation of lattice cells of the discretized domain in a block sparse data structure stack, wherein storing the representation of lattice cells of the discretized domain in the block sparse data structure stack comprises
storing first level information in a first block sparse data structure and second level information in a second block sparse data structure, wherein each first block of the first block sparse data structure comprises respective first cells and each second block of the second block sparse data structure comprises respective second cells, and
storing ghost layer information, wherein storing ghost layer information comprises storing block indices of ghost blocks comprising the ghost layer, and wherein
performing the at least one first time step of the lattice Boltzmann modelling process comprises assigning each ghost block to a thread group comprising threads that use a same portion of the shared memory and assigning each respective lattice cell to a thread of the thread group.

8. A system comprising:
one or more hardware processors; and
a shared memory coupled with at least a single hardware processor of the one or more hardware processors;
wherein the single hardware processor is configured to
obtain a representation of lattice cells of a discretized domain, wherein the discretized domain comprises a first level comprising first lattice cells and a second level comprising second lattice cells, wherein a size of the second lattice cells is smaller than a size of the first lattice cells, wherein the first lattice cells comprise a first layer of first interface lattice cells and the second lattice cells comprise a second layer of second interface lattice cells, wherein the first interface lattice cells and the second interface lattice cells are neighboring cells at an interface between the first level and the second level,
allocate a ghost layer at the first level, wherein the ghost layer comprises a layer of first ghost lattice cells adjacent to the first layer of first interface lattice cells and overlapping the second layer of second interface cells, wherein allocating the ghost layer comprises allocating the ghost layer in the shared memory that is accessed by the single hardware processor,
define, for each lattice cell, velocity distributions along lattice directions corresponding to each of a predetermined number of lattice vectors associated with different lattice directions,
perform at least one first time step of a lattice Boltzmann modelling process, wherein performing the at least one first time step comprises performing a first accumulate operation to store, on the ghost layer, velocity distributions of the second layer of second interface cells, and
provide a result of the at least one first time step of the lattice Boltzmann simulation.

9. The system of claim 8, wherein the single hardware processor is configured to perform the at least one first time step of the lattice Boltzmann modelling process by being configured to:
perform a first first-level collision operation on the first level to update velocity distributions of the first level,
perform a first second-level collision operation on the second level to update velocity distributions of the second level,
perform an explosion operation to populate velocity distributions of the second layer of second interface cells using velocity distributions of the first level,
perform a first first-level streaming operation on the first level to update velocity distributions of the first level,
perform a first second-level streaming operation on the second level to update velocity distributions of the second level,
perform a second second-level collision operation on the second level to update velocity distributions of the second level,
perform a second accumulate operation to store, on the ghost layer, the velocity distributions of the second layer of second interface cells,
perform a second second-level streaming operation on the second level to update the velocity distributions of the second level, and
perform a coalesce operation, wherein the coalesce operation comprises reading and averaging the velocity distributions stored on the ghost layer to update velocity distributions of the first level.

10. The system of claim 9, wherein the collision operations and the accumulate operations are executed in a single computational kernel, wherein the accumulate operations are performed as atomic writes.

11. The system of claim 9, wherein the explosion operations and the streaming operations are executed in a single computational kernel.

12. The system of claim 9, wherein the coalescence operations and the streaming operations are executed in a single computational kernel.

13. The system of claim 9, wherein the collision operations and the streaming operations are executed in a single computational kernel.

14. The system of claim 8, wherein the single hardware processor is further configured to
store the representation of lattice cells of the discretized domain in a block sparse data structure stack by being configured to
store first level information in a first block sparse data structure and second level information in a second block sparse data structure, wherein each first block of the first block sparse data structure comprises respective first cells and each second block of the second block sparse data structure comprises respective second cells, and
store ghost layer information by being configured to store block indices of ghost blocks comprising the ghost layer, and wherein
the single hardware processor is configured to perform the at least one first time step of the lattice Boltzmann modelling process by being configured to assign each ghost block to a thread group comprising threads that use a same portion of the shared memory and assign each respective lattice cell to a thread of the thread group.

15. The system of claim 8, wherein the single hardware processor is a Graphics Processing Unit (GPU).

16. The system of claim 15, wherein the shared memory is a thread register of the GPU.

17. A non-transitory computer-readable medium tangibly encoding instructions that, when executed, cause one or more processors to perform method operations comprising:
obtaining a representation of lattice cells of a discretized domain, wherein the discretized domain comprises a first level comprising first lattice cells and a second level comprising second lattice cells, wherein a size of the second lattice cells is smaller than a size of the first lattice cells, wherein the first lattice cells comprise a first layer of first interface lattice cells and the second lattice cells comprise a second layer of second interface lattice cells, wherein the first interface lattice cells and the second interface lattice cells are neighboring cells at an interface between the first level and the second level,
allocating a ghost layer at the first level, wherein the ghost layer comprises a layer of first ghost lattice cells adjacent to the first layer of first interface lattice cells and overlapping the second layer of second interface cells, wherein allocating the ghost layer comprises allocating the ghost layer in a shared memory that is accessed by a single hardware processor,
defining, for each lattice cell, velocity distributions along lattice directions corresponding to each of a predetermined number of lattice vectors associated with different lattice directions,
performing at least one first time step of a lattice Boltzmann modelling process, wherein performing the at least one first time step comprises performing a first accumulate operation to store, on the ghost layer, velocity distributions of the second layer of second interface cells, and
providing a result of the at least one first time step of the lattice Boltzmann simulation.

18. The non-transitory computer-readable medium of claim 17, wherein performing the at least one first time step of the lattice Boltzmann modelling process further comprises
performing a first first-level collision operation on the first level to update velocity distributions of the first level,
performing a first second-level collision operation on the second level to update velocity distributions of the second level,
performing an explosion operation to populate velocity distributions of the second layer of second interface cells using velocity distributions of the first level,
performing a first first-level streaming operation on the first level to update velocity distributions of the first level,
performing a first second-level streaming operation on the second level to update velocity distributions of the second level,
performing a second second-level collision operation on the second level to update velocity distributions of the second level,
performing a second accumulate operation to store, on the ghost layer, the velocity distributions of the second layer of second interface cells,
performing a second second-level streaming operation on the second level to update the velocity distributions of the second level, and
performing a coalesce operation, wherein performing the coalesce operation comprises reading and averaging the velocity distributions stored on the ghost layer to update velocity distributions of the first level.

19. The non-transitory computer-readable medium of claim 18, wherein the collision operations and the accumulate operations are executed in a single computational kernel, wherein the accumulate operations are performed as atomic writes.

20. The non-transitory computer-readable medium of claim 18, wherein the explosion operations and the streaming operations are executed in a single computational kernel.

21. The non-transitory computer-readable medium of claim 18, wherein the coalescence operations and the streaming operations are executed in a single computational kernel.

22. The non-transitory computer-readable medium of claim 18, wherein the collision operations and the streaming operations are executed in a single computational kernel.

23. The non-transitory computer-readable medium of claim 17, wherein the method operations further comprise
storing the representation of lattice cells of the discretized domain in a block sparse data structure stack, wherein storing the representation of lattice cells of the discretized domain in the block sparse data structure stack comprises
storing first level information in a first block sparse data structure and second level information in a second block sparse data structure, wherein each first block of the first block sparse data structure comprises respective first cells and each second block of the second block sparse data structure comprises respective second cells, and
storing ghost layer information, wherein storing ghost layer information comprises storing block indices of ghost blocks comprising the ghost layer, and wherein
performing the at least one first time step of the lattice Boltzmann modelling process comprises assigning each ghost block to a thread group comprising threads that use a same portion of the shared memory and assigning each respective lattice cell to a thread of the thread group.
